(19) United States
(12) Patent Application Publication
(10) Pub. No.: US 2014/0110375 A1
(43) Pub. Date: Apr. 24, 2014

(54) SURFACE PROCESSING DEVICE AND SURFACE PROCESSING METHOD

(71) Applicants: Takehito Kobayashi, Miyoshi-shi (JP); Noriyuki Ueno, Toyota-shi (JP); Katsuya Kurachi, Ichinomiya-shi (JP)

(72) Inventors: Takehito Kobayashi, Miyoshi-shi (JP); Noriyuki Ueno, Toyota-shi (JP); Katsuya Kurachi, Ichinomiya-shi (JP)

(73) Assignee: TOYOTA JIDOSHA KABUSHIKI KAISHA, Toyota-shi (JP)

(21) Appl. No.: 14/125,425

(22) PCT Filed: Jun. 13, 2011
(86) PCT No.: PCT/JP2011/063518

§ 371 Date: Dec. 11, 2013

(51) Int. Cl. H01J 37/04

(52) U.S. Cl. CPC H01J 37/04
USPC 216/67; 156/345.44

(57) ABSTRACT

In the present invention, the form in which roughness is formed on the surface of an article being processed through plasma exposure is controlled by varying the frequency for a main voltage applied to two discharge electrodes, a conductive housing and a rod shaped electrode, provided in a plasma generating unit and the frequency for a bias voltage applied between the conductive housing (2) and the article being processed.

### TECHNICAL FIELD

The present invention relates to a device and method for processing the surface of a workpiece by plasma irradiation.

### BACKGROUND ART

Since a cylinder liner (sleeve) mounted in a bore portion of a cylinder block of an internal combustion engine is subjected to sliding contact with a piston, high wear resistance is required. For improvement of the wear resistance of a sliding member such as the cylinder liner, improvement of anti-seizure, reduction of friction resistance, and reduction of lubricant consumption amount are desired. Thus, the surface is preferably a rough surface that has a certain amount of asperity rather than a smooth surface. A technique for roughly processing the surface by plasma irradiation has been proposed as a surface processing method for such a purpose.

As a plasma irradiation device for radiating plasma, devices have been proposed that use a gun-shaped nozzle in which a rod-like electrode is arranged in a tubular conductive housing, and that include a parallel-plate type unit in which a plate-like electrodes are arranged to face each other. Conventionally, Patent Documents 1 to 4 disclose techniques for stabilizing generation of plasma under atmospheric pressure, and increasing the power of plasma by applying a bias voltage between a discharge electrode and a workpiece.

### PRIOR ART DOCUMENTS

### Patent Documents

Patent Document 1: Japanese Laid-Open Patent Publication No. 2008-010373
Patent Document 2: Japanese Laid-Open Patent Publication No. 2002-018276
Patent Document 3: Japanese Laid-Open Patent Publication No. 2006-216468
Patent Document 4: Japanese Laid-Open Patent Publication No. 08-203869

### SUMMARY OF THE INVENTION

### Problems that the Invention is to Solve

As a result of experimentation performed by inventors, it was discovered that the surface suitable for improving the wear resistance should include minute recesses with a depth of 0.5 micrometers or less and deeper recesses with a depth of 5 micrometers formed at intervals of approximately 1 millimeter as shown in FIG. 5. However, to allow oil permeate into deep parts of the recesses by capillary action, the deepest parts of the recesses must have an acute angle. It is difficult to perform such fine processing with a machining center or a laser beam machine.

When plasma irradiation is used, it is possible to form recesses with the deepest parts having an acute angle. However, according to the above-mentioned conventional plasma treatment technique, only recesses with constant depth are formed. It is difficult to form a surface on which shallow recesses and deep recesses are mixed under the current circumstances.

Accordingly, it is an objective of the present invention to provide a surface processing device and surface processing method that easily control the manner in which asperity is formed on a surface of a workpiece by plasma irradiation.

### Means for Solving the Problems

To achieve the foregoing objective, the present invention provides a surface processing device for processing a surface of a workpiece by plasma irradiation. The surface processing device includes a plasma generating unit for generating plasma in response to application of a voltage between two electrodes, a first power source for supplying a main voltage to be applied between the two electrodes of the plasma generating unit, and a second power source for supplying a bias voltage to be applied between one of the electrodes of the plasma generating unit and the workpiece. The manner in which asperity is formed on the surface of the workpiece through plasma irradiation is controlled by setting of a voltage waveform of the bias voltage.

The varying pattern of the intensity of the plasma radiated on the workpiece is changed depending on the voltage waveform of the bias voltage, and the pattern of the asperity formed on the surface of the workpiece is changed. Thus, the manner in which the asperity is formed on the surface of the workpiece through plasma irradiation is easily and appropriately controlled by setting the voltage waveform of the bias voltage as necessary. Thus, according to the above-mentioned configuration, the manner in which the asperity is formed on the surface of the workpiece through plasma irradiation is easily controlled.

To achieve the foregoing objective, the present invention provides another surface processing device for processing a surface of a workpiece by plasma irradiation. The surface processing device includes a plasma generating unit for generating plasma in response to application of a voltage between two electrodes, a first AC power source for supplying a main voltage to be applied between the two electrodes of the plasma generating unit, and a second AC power source for supplying a bias voltage to be applied between one of the electrodes of the plasma generating unit and the workpiece. The manner in which asperity is formed on the surface of the workpiece through plasma irradiation is controlled by setting of variation of at least one of the frequency and the amplitude of the bias voltage.

When the frequency of the bias voltage is set different from the frequency of the main voltage, the power of plasma radiated on the workpiece changes periodically, and the depth of the recesses formed on the surface of the workpiece is changed periodically. The power of plasma radiated on the workpiece is changed also by changing the amplitude of the bias voltage, and the depth of the recesses formed on the surface of the workpiece is changed. The forming pattern of the recesses is easily changed by changing the frequency or the amplitude of the bias voltage. Thus, according to the above-mentioned configuration, the manner in which the asperity is formed on the surface of the workpiece by plasma irradiation is easily controlled.

In the surface processing device described above, the manner in which the asperity is formed is preferably controlled to form first recesses on the surface of the workpiece and to form second recesses, which are deeper than the first recesses, at certain intervals on the surface of the workpiece. In this case, the wear resistance of the surface of the workpiece is improved. The wear resistance of the surface of the workpiece is particularly improved by setting the depth of the second recesses to 5 micrometers and the intervals of the second recesses to 1 millimeter.

In the surface processing device of the present invention, if it is desired to easily control the manner in which the asperity is formed on the surface of the workpiece, a waveform variable unit, which varies the voltage waveform of the bias voltage is preferably provided.

To achieve the foregoing objective, the present invention provides a further surface processing device for processing a surface of a workpiece by plasma irradiation. The surface processing device includes a plasma generating unit for generating plasma in response to application of a voltage between two electrodes, a first AC power source for supplying a main voltage to be applied between the two electrodes of the plasma generating unit, and a second AC power source for supplying a bias voltage to be applied between one of the electrodes of the plasma generating unit and the workpiece, the bias voltage having the frequency different from the frequency of the main voltage.

When the frequency of the bias voltage is set to be different from the frequency of the main voltage, the power of the plasma radiated on the workpiece is changed periodically, and the depth of the recesses formed on the surface of the workpiece is changed periodically. Such a forming pattern of the recesses is easily changed by changing the frequency of the bias voltage. Thus, according to the above-mentioned configuration, the manner in which the asperity is formed on the surface of the workpiece by plasma irradiation is easily controlled.

For improvement of the wear resistance of the surface of the workpiece, the frequency of the main voltage and the frequency of the bias voltage are desirably set to form the first recesses on the surface of the workpiece and to form the second recesses, which are deeper than the first recesses, at certain intervals on the surface of the workpiece. The wear resistance of the surface of the workpiece is particularly improved by setting the depth of the second recesses to 5 micrometers and the intervals of the second recesses to 1 millimeter.

In the surface processing device of the present invention, if it is desired to easily control the manner in which the asperity is formed on the surface of the workpiece, a frequency variable unit, which varies the frequency of the second AC power source, is preferably provided.

The surface processing device of the present invention as described above includes, as the two electrodes, for example, a conductive housing having a space formed therein and a rod-like electrode arranged inside the conductive housing. The plasma generating unit is configured to generate plasma by injecting a plasma source gas into the conductive housing in a state in which the main voltage is applied between the conductive housing and the rod-like electrode. The surface processing device may also include, as the two electrodes, a pair of flat plate electrodes arranged parallel to each other. The plasma generating unit is configured to generate plasma by injecting a plasma source gas into between the flat plate electrodes while applying the main voltage between the flat plate electrodes.

If it is desired to efficiently perform surface processing of an inner circumferential surface of a workpiece that is formed into a circular tube, the plasma generating unit may be inserted inside the workpiece that is formed into a circular tube. Then, the workpiece and the plasma generating unit may be rotated relative to each other to process the inner circumferential surface of the workpiece. The plasma generating unit is secured to a rotating member and is arranged to be able to radiate the plasma outward of the rotational direction of the rotating member. The processing efficiency is improved by processing the inner circumferential surface of the workpiece by inserting the plasma generating unit inside the workpiece that is formed into a circular tube, and rotating the rotating member while radiating the plasma from the plasma generating unit. If it is desired to further improve the processing efficiency, a multiple number of the plasma generating units may be secured to the rotating member. The plasma source gas is easily supplied to the rotating plasma generating units by using a hollow rotary shaft of the rotating member as a supply passage of the plasma source gas to the plasma generating unit.

The surface processing device of the present invention is suitable for processing a sliding surface of the workpiece. The surface processing device of the present invention is suitable for processing an engine component made of an aluminum alloy, and in particular, is suitable for processing a sealing member of an engine such as a cylinder liner of the engine.

To achieve the foregoing objective, the present invention provides a surface processing method for processing a surface of a workpiece by irradiating a surface of a workpiece with plasma generated in response to application of a main voltage between two electrodes. The method includes controlling the manner in which asperity is formed on the surface of the workpiece through plasma irradiation by setting a voltage waveform of a bias voltage to be applied between one of the two electrodes and the workpiece.

Depending on the voltage waveform of the bias voltage, the varying pattern of the intensity of the plasma radiated on the workpiece is changed, and the manner in which asperity is formed on the surface of the workpiece is changed. Thus, by setting the voltage waveform of the bias voltage as necessary, the manner in which the asperity is formed on the surface of the workpiece through plasma irradiation is easily and appropriately controlled. Therefore, according to the above-mentioned surface processing method, the manner in which the asperity is formed on the surface of the workpiece by plasma irradiation is easily controlled.

To achieve the foregoing objective, the present invention provides another surface processing method for processing a surface of a workpiece by irradiating a surface of a workpiece with plasma generated in response to application of a main voltage between two electrodes. The method includes controlling the manner in which asperity is formed on the surface of the workpiece through plasma irradiation by applying a bias voltage between one of the two electrodes and the workpiece and setting the frequency of the main voltage supplied as an AC voltage and the frequency of the bias voltage also supplied as the AC voltage.

When the frequency of the bias voltage is set to be different from the frequency of the main voltage, the power of the plasma radiated on the workpiece is changed periodically, and the depth of the recesses formed on the surface of the workpiece is changed periodically. The forming pattern of the recesses is easily changed by changing the frequency of the bias voltage. Thus, according to the above-mentioned surface processing method, the manner in which the asperity is formed on the surface of the workpiece by plasma irradiation is easily controlled.

For improvement of the wear resistance of the surface of the workpiece, the manner in which the asperity is formed is controlled to form first recesses on the surface of the workpiece and to form second recesses, which are deeper than the first recesses, at certain intervals on the surface of the workpiece. The wear resistance of the surface of the workpiece is particularly improved by setting the depth of the second recesses to 5 micrometers, and the intervals of the second recesses to 1 millimeter.

In the surface processing method of the present invention, if it is desired to easily control the manner in which the asperity is formed on the surface of the workpiece, the voltage waveform of the bias voltage may be variable.

To achieve the foregoing objective, the present invention provides a further surface processing method for processing a surface of a workpiece by irradiating a surface of a workpiece with plasma generated in response to application of a main voltage between two electrodes. The method includes applying a bias voltage between one of the two electrodes and the workpiece, and setting the frequency of the main voltage supplied as an AC voltage to be different from the frequency of the bias voltage also supplied as the AC voltage.

When the frequency of the bias voltage is set to be different from the frequency of the main voltage, the power of the plasma radiated on the workpiece is changed periodically, and the depth of the recesses formed on the surface of the workpiece is changed periodically. The forming pattern of the recesses is easily changed by changing the frequency of the bias voltage. Thus, according to the above-mentioned surface processing method, the manner in which the asperity is formed on the surface of the workpiece by plasma irradiation is easily controlled.

For improvement of the wear resistance of the surface of the workpiece, the manner in which the asperity is formed is controlled to form first recesses on the surface of the workpiece and to form second recesses, which are deeper than the first recesses, at certain intervals on the surface of the workpiece. The wear resistance of the surface of the workpiece is particularly improved by setting the depth of the second recesses to 5 micrometers, and the intervals of the second recesses to 1 millimeter.

In the surface processing method of the present invention, if it is desired to easily control the manner in which the asperity is formed on the surface of the workpiece, the frequency of the bias voltage may be variable.

According to the surface processing method of the present invention as described above, for example, the two electrodes include a conductive housing having a space formed therein and a rod-like electrode arranged inside the conductive housing. Plasma is generated by injecting a plasma source gas into the conductive housing in a state in which the main voltage is applied between the conductive housing and the rod-like electrode. The two electrodes may also be a pair of flat plate electrodes arranged parallel to each other. Plasma is generated by injecting a plasma source gas into between the flat plate electrodes while applying the main voltage between the flat plate electrodes.

The surface processing method of the present invention is suitable for processing a sliding surface of the workpiece. The surface processing device of the present invention is suitable for processing an engine component made of an aluminum alloy, and is particularly optimal for processing a sealing member of an engine such as a cylinder liner of the engine.

### BRIEF DESCRIPTION OF THE DRAWINGS

FIG. 1 is a schematic diagram illustrating the configuration of a surface processing device according to a first embodiment of the present invention;

FIG. 2 is a schematic diagram illustrating the configuration of a surface processing device according to a second embodiment of the present invention;

FIG. 3 is a schematic diagram illustrating the configuration of a surface processing device according to a third embodiment of the present invention;

FIG. 4 is a cross-sectional view illustrating the configuration of the plasma generating unit taken along line A-A of FIG. 3; and

FIG. 5 is a cross-sectional view illustrating asperity of a surface having high wear resistance.

### MODES FOR CARRYING OUT THE INVENTION

### First Embodiment

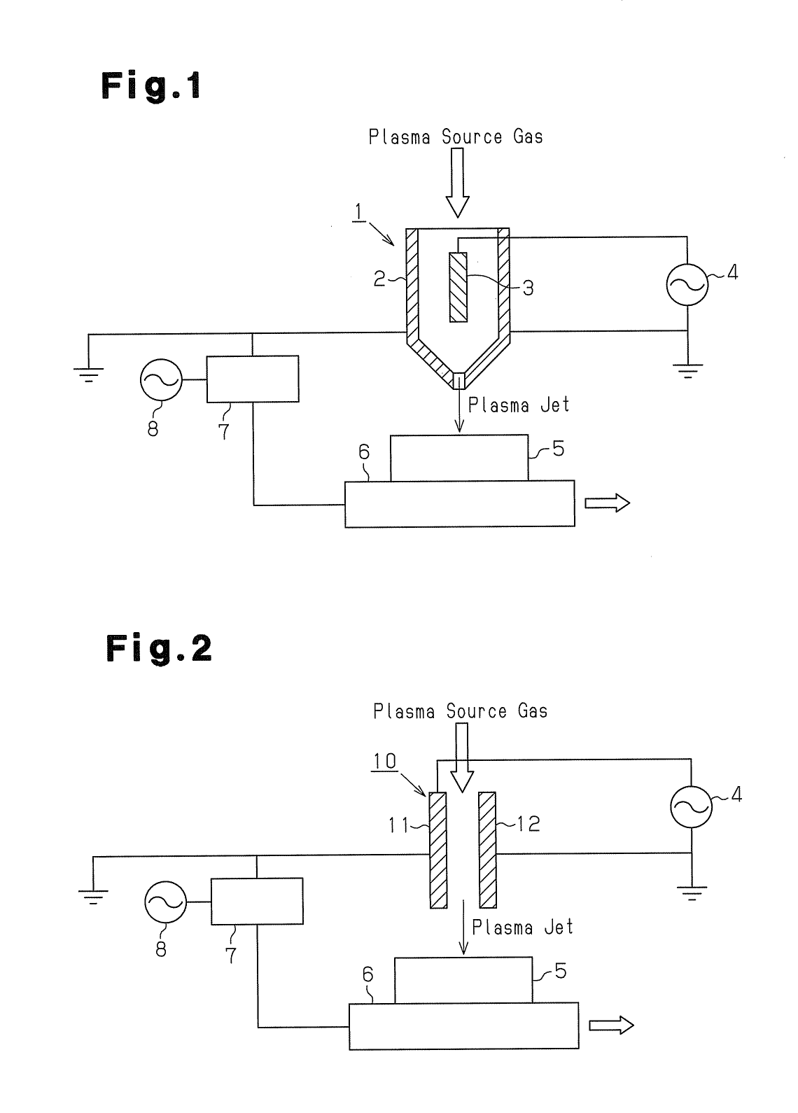

A first embodiment of the present invention will now be described with reference to FIG. 1. The objective of a surface processing device and a surface processing method of the first embodiment is to apply surface treatment on a sliding surface of a workpiece by plasma irradiation for improving the wear resistance. The device and the method are used for, for example, surface processing of the sliding surface of a sealing member of an engine such as a cylinder liner made of an aluminum alloy.

As shown in FIG. 1, a plasma generating unit 1 of the surface processing device of the first embodiment includes two discharge electrodes, that is, a conductive housing 2, which is a substantially circular tapered tube having a space inside, and a rod-like electrode 3, which is arranged inside the conductive housing 2. A main voltage of a sine wave alternating current generated by a first power source, or a first AC power source 4 in this embodiment, is applied between the conductive housing 2 and the rod-like electrode 3.

A movable table 6 is arranged below the plasma generating unit 1, and a workpiece 5 is located on the upper surface of the movable table 6. A bias voltage of a sine wave alternating current generated by a second power source, or a second AC power source 8 in this embodiment, is applied between the movable table 6 and the workpiece 5, and the above-mentioned conductive housing 2. In the first embodiment, the frequency of the bias voltage applied between the movable table 6 and the workpiece 5, and the above-mentioned conductive housing 2 can be changed by a waveform variable unit or a frequency variable unit, which is an inverter 7 in the first embodiment.

The operations of the first embodiment configured as described above will now be described.

When processing the surface of the workpiece 5, the main voltage is applied between the conductive housing 2 and the rod-like electrode 3 of the plasma generating unit 1. At the same time, the bias voltage having a different frequency from the main voltage is applied between the conductive housing 2 and the workpiece 5 via the movable table 6.

When a plasma source gas is supplied to the inside of the conductive housing 2 from the upper section of the plasma generating unit 1 in this state, plasma is generated by the main voltage applied between the conductive housing 2 and the rod-like electrode 3. Then, the plasma is discharged from the distal end of the plasma generating unit 1 toward the workpiece 5. In the first embodiment, compressed air is used as the plasma source gas.

The movable table 6 is moved at a predetermined speed while irradiating the workpiece 5 with a plasma jet. Thus, the relative position between the plasma generating unit 1 and the workpiece 5 is displaced, and the plasma irradiation position on the surface of the workpiece 5 is moved. Accordingly, surface processing of the workpiece 5 is performed.

According to the surface processing device, since the bias voltage is applied between the conductive housing 2 and the workpiece 5, the plasma generated at the plasma generating unit 1 is attracted to the workpiece 5 by the bias voltage. Thus, as compared to a case in which the bias voltage is not applied, the surface of the workpiece 5 is irradiated with a strong plasma jet. Also, since the bias voltage is an AC voltage, the intensity of the plasma jet radiated on the surface of the workpiece 5 varies, thus forming relatively small asperity on the surface of the workpiece 5.

Furthermore, in the first embodiment, since the frequency of the bias voltage differs from the frequency of the main voltage, the difference between the frequency of the bias voltage and the main voltage causes the force of the plasma jet to instantaneously increase at a certain cycle. At that time relatively deep recesses are formed on the surface of the workpiece 5 at certain intervals by the strong plasma jet.

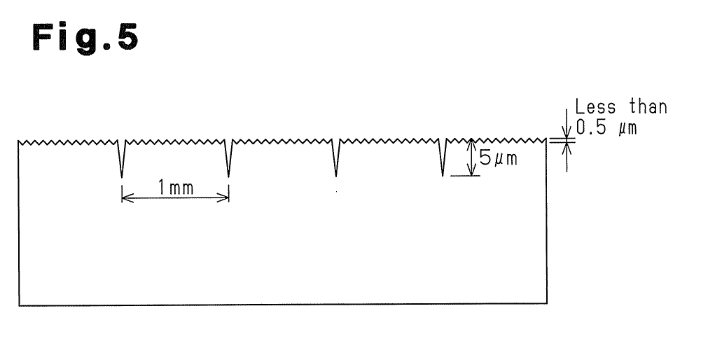

In the first embodiment, the surface of the workpiece 5 is processed with the frequency of the main voltage set to 20 kHz, the frequency of the bias voltage set to 17 kHz, and the moving speed of the movable table 6 set to 10 millimeters/sec. In this case, deep recesses having a depth of 5 micrometers are formed at intervals of approximately 1 millimeter on the surface on which minute recesses with a depth of 0.5 micrometers or less are formed as shown in FIG. 5. According to such surface processing, it is confirmed that the Vickers hardness of the aluminum alloy changes from 100 to 110, which is measured before treatment, to 180 to 190.

The first embodiment has the following advantages.

(1) By changing the frequency of the main voltage and the bias voltage, the deep recesses are formed at certain intervals on the surface of the workpiece 5 on which the minute recesses are formed. Since oil permeates in the deep parts of the deep recesses by capillary action on such a surface, oil retention performance is increased, and thus the wear resistance is improved.

(2) In the first embodiment, since the intensity pattern of the plasma jet, or the pattern of the asperity formed on the surface of the workpiece 5 is changed by only changing the frequency of the bias voltage, the manner in which the asperity is formed on the surface of the workpiece 5 is easily controlled.

(3) The wear resistance of the workpiece 5 is significantly improved by processing the surface of the workpiece 5 by plasma irradiation so as to form, on the surface on which the minute first recesses of 0.5 micrometers or less are formed, the deeper second recesses with a depth of 5 micrometers at intervals of 1 millimeter.

### Second Embodiment

A second embodiment of the present invention will now be described with reference to FIG. 2. Like or the same reference numerals are given to those components that are like or the same as the corresponding components of the above-mentioned embodiment and detailed explanations are omitted. In a surface processing device of the second embodiment, the configuration of the plasma generating unit of the device of the first embodiment is modified.

As shown in FIG. 2, a plasma generating unit 10 of the surface processing device of the second embodiment includes a pair of flat plate electrodes 11, 12, which are arranged parallel to each other, as two discharge electrodes. The plasma generating unit 10 generates plasma by injecting a plasma source gas into between the flat plate electrodes 11, 12 while applying the main voltage between the flat plate electrodes 11, 12. Also, in the surface processing device, the bias voltage generated by the second AC power source 8 is applied between one of the flat plate electrodes (11) and the workpiece 5. The frequency of the bias voltage is variable by the inverter 7.

The surface processing device including the plasma generating unit 10 configured as described above performs the surface processing that is the same as the device of the first embodiment. Thus, by applying the bias voltage having different frequency from the frequency of the main voltage, the force of the plasma jet radiated on the workpiece 5 is varied, and deeper second recesses are formed at certain intervals on the surface of the workpiece 5 on which the minute first recesses are formed.

### Third Embodiment

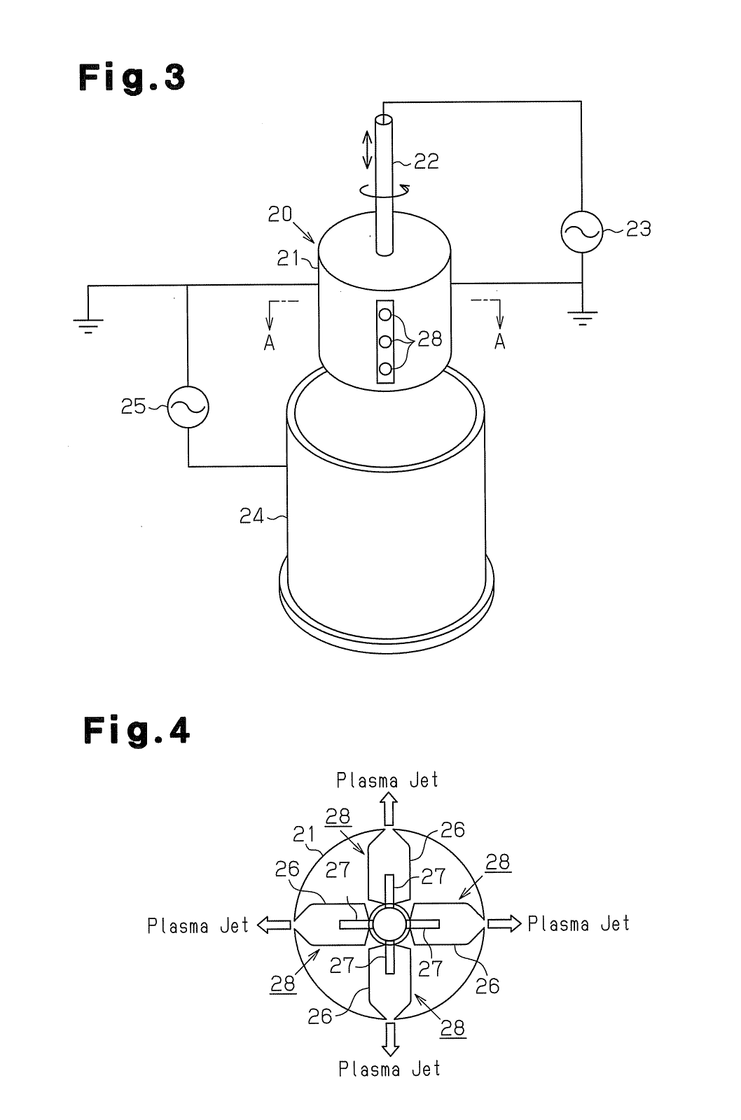

A third embodiment of the present invention will now be described with reference to FIGS. 3 and 4. Like or the same reference numerals are given to those components that are like or the same as the corresponding components of the above-mentioned embodiments and detailed explanations are omitted. A surface processing device of the third embodiment is suitable for machining, for example, the inner circumferential surface of a component having a circular tube shape such as a cylinder liner.

As shown in FIG. 3, a plasma irradiation device 20 of the surface processing device of the third embodiment includes a cylindrical rotating member 21 on which plasma generating units 28 are secured, and a hollow circular tube-like rotary shaft 22, which rotates integrally with the rotating member 21. The rotating member 21 is integrally rotational with the rotary shaft 22, and can be displaced in the direction of the rotary shaft. The rotating member 21 can be inserted inside the workpiece, which is a cylinder liner 24 in the third embodiment, in accordance with the displacement in the axial direction. In the third embodiment, the plasma source gas is supplied to each of the plasma generating units 28 through the inside of the rotary shaft 22, which is formed to be hollow.

In the surface processing device, the main voltage of a sine wave alternating current generated by a first AC power source 23 is applied to two discharge electrodes, which will be discussed below, of the plasma generating units 28 provided on the rotating member 21. The bias voltage of a sine wave alternating current generated by a second AC power source 25 is applied between one of such discharge electrodes of each plasma generating unit 28 (conductive housing 26) and the cylinder liner 24.

As shown in FIG. 4, four plasma generating units 28 are secured inside the rotating member 21 at intervals of 90° about the rotary shaft. Each plasma generating unit 28 includes two discharge electrodes, that is, the conductive housing 26, which is a substantially circular tapered tube having a space inside, and a rod-like electrode 27, which is located inside the associated conductive housing 26. In the surface processing device, the four plasma generating units 28 are each arranged in three rows in the direction of the rotational axis of the rotating member 21. Thus, the total of twelve plasma generating units 28 are secured to the rotating member 21.

The operations of the third embodiment configured as described above will now be described.

When processing the surface of the inner circumferential surface of the cylinder liner 24, the rotating member 21 of the plasma irradiation device 20 is inserted in the cylinder liner 24. Then, while applying the main voltage between the conductive housings 26 and the rod-like electrodes 27 of the plasma generating units 28, the plasma source gas is injected into the plasma generating units 28 via the rotary shaft 22, which serves as the supply passage, so that the plasma jet is discharged from the distal ends of the plasma generating units 28. The rotating member 21 is then rotated while being displaced in the direction of the rotational axis, so that the plasma is sequentially radiated on the inner circumferential surface of the cylinder liner 24.

At this time, in the surface processing device, the bias voltage is applied between the conductive housings 26 of the plasma generating units 28 and the cylinder liner 24. Thus, the plasma generated at the plasma generating units 28 is attracted to the cylinder liner 24 by the bias voltage, and a strong plasma jet is radiated on the inner circumferential surface of the cylinder liner 24 as compared to the case in which the bias voltage is not applied. Also, since the bias voltage is the AC voltage, the intensity of the plasma jet radiated on the inner circumferential surface of the cylinder liner 24 varies, and thus relatively small asperity is formed on the inner circumferential surface of the cylinder liner 24.

Furthermore, in the third embodiment, since the frequency of the bias voltage is set different from the frequency of the main voltage, the force of the plasma jet is instantaneously increased at a certain cycle due to the difference between the frequency of the bias voltage and the main voltage. Thus, relatively deep recesses are formed on the inner circumferential surface of the cylinder liner 24 at certain intervals by the strong plasma jet generated at this time.

In the third embodiment, the frequency of the main voltage is set to 20 kHz, and the frequency of the bias voltage is set to 17 kHz. Also, the rotational speed of the rotating member 21 is set such that the speed of the relative movement of the plasma generating units 28 and the cylinder liner 24 will be 10 millimeters/sec. Thus, in the third embodiment also, the deep recesses having a depth of 5 micrometers are formed at intervals of approximately 1 millimeter on the surface on which the minute recesses having a depth of 0.5 micrometers or less are formed as shown in FIG. 5.

The third embodiment has the following advantages in addition to the advantages (1) to (3).

(4) In the third embodiment, the plasma generating units 28 are inserted inside the cylinder liner 24, which is formed into a circular tube, and the cylinder liner 24 and the plasma generating units 28 are rotated relative to each other to process the inner circumferential surface of the cylinder liner 24. More specifically, the plasma generating units 28, which are secured to the rotating member 21 and are arranged to be able to radiate the plasma outward of the rotational direction of the rotating member 21, are inserted inside the cylinder liner 24, which is formed into a circular tube. Then, the inner circumferential surface of the cylinder liner 24 is processed by rotating the rotating member 21 while radiating the plasma from the plasma generating units 28. Furthermore, in the third embodiment, the plasma generating units 28 are secured to the rotating member 21. Thus, the inner circumferential surface of the cylinder liner 24, which is formed into a circular tube, is efficiently processed.

(5) In the third embodiment, since the hollow rotary shaft 22 of the rotating member 21 is used as a path for supplying the plasma source gas to the plasma generating units 28, the plasma source gas is easily and properly supplied to the rotating plasma generating units 28.

(6) The inner circumferential surface of the cylinder liner 24 is entirely processed in a short period of time, thus improving the productivity.

The illustrated embodiments may be modified as follows.

In the third embodiment, the plasma source gas is supplied to the plasma generating units 28 using the inside of the hollow rotary shaft 22 as the supply passage. However, the plasma source gas may be supplied through other passage if possible.

In the third embodiment, twelve plasma generating units 28 are secured to the rotating member 21. However, the number and the position of the plasma generating units 28 secured to the rotating member 21 may be changed as necessary.

In the third embodiment, as the plasma generating units 28, a gun-type nozzle is used that includes the rod-like electrode 27 arranged inside the associated tubular conductive housing 26. However, other types of plasma generating unit may be employed such as the parallel flat plate type as in the second embodiment.

In the third embodiment, the case in which the inner circumferential surface of the cylinder liner 24 is processed is described. However, the surface processing device and the surface processing method of the third embodiment may be applied to surface processing of the inner circumferential surface of a workpiece other than the cylinder liner 24 as long as the workpiece is formed into a circular tube.

In the above described embodiments, the deep recesses having a depth of 5 micrometers are formed at intervals of approximately 1 millimeter on the surface on which the minute recesses having a depth of 0.5 micrometers or less are formed. However, the surface of the workpiece may be processed into other forms. That is, according to the surface processing device and the surface processing method of the present invention, the manner in which the asperity is formed on the surface of the workpiece through plasma irradiation is easily controlled, and required surface property is easily obtained.

In the above described embodiments, the frequency of the main voltage is set to 20 kHz, and the frequency of the bias voltage is set to 17 kHz. However, the frequency may be changed in accordance with the required surface property.

In the above described embodiments, the speed of the relative movement of the plasma generating unit with respect to the workpiece is set to 10 millimeters/sec. However, such relative displacement speed may be changed in accordance with the required surface property.

In the above described embodiments, the frequency of the bias voltage is variable. However, the frequency of the bias voltage may be fixed if the object to be processed is fixed. In that case also, as long as the frequency of the bias voltage is different from the frequency of the main voltage, the force of the plasma radiated on the workpiece is changed periodically, and thus the pattern of the asperity formed on the surface of the workpiece is changed periodically. If the frequency of the main voltage and the frequency of the bias voltage are set appropriately, the surface processing is performed such that high wear resistance is ensured.

In the above described embodiments, the manner in which the asperity is formed on the surface of the workpiece through plasma irradiation is controlled by the frequency of the bias voltage. However, such control can be performed by changing the amplitude of the bias voltage. For example, when the frequency and the amplitude of the main voltage is constant, the intensity of the plasma radiated on the workpiece is periodically changed by changing the amplitude of the bias voltage periodically, and thus the depth of the recesses formed on the surface of the workpiece is periodically changed.

In the above described embodiments, the voltage of a sine wave alternating current is used as the main voltage and the bias voltage. However, the voltage waveform may be changed to a voltage of any waveform such as a rectangular wave alternating current or a triangular wave alternating current. In any case, by changing the voltage waveform of the bias voltage, the variation pattern of the intensity of the plasma generated at the plasma generating unit is changed, and thus the pattern in which the asperity is formed on the surface of the workpiece is changed. Thus, by setting the voltage waveform of the bias voltage as necessary, the manner in which the asperity is formed on the surface of the workpiece through plasma irradiation is easily and appropriately controlled. In this case also, by setting the voltage waveform of the bias voltage to be variable, the manner in which the asperity is formed on the surface of the workpiece can be easily changed.

In the above described embodiments, the compressed air is used as the plasma source gas. However, other gases such as helium, neon, argon, or nitrogen may be used.

The surface processing device and the surface processing method of the present invention are suitable for surface processing of, for example, the engine components and the sealing member of the engine made of an aluminum alloy such as the cylinder liner, but may be applied to surface processing of other workpiece including, for example, a workpiece made of material other than aluminum alloy such as iron.

### DESCRIPTION OF THE REFERENCE NUMERALS

1 . . . plasma generating unit, 2 . . . conductive housing (one of two electrodes), 3 . . . rod-like electrode (one of two electrodes), 4 . . . first AC power source (first power source, first AC power source), 5 . . . workpiece, 6 . . . movable table, 7 . . . inverter (waveform variable unit, frequency variable unit), 8 . . . second AC power source (second power source, second AC power source), 10 . . . plasma generating unit, 11 . . . flat plate electrode (one of two electrodes), 12 . . . flat plate electrode (one of two electrodes), 20 . . . plasma irradiation device, 21 . . . rotating member, 22 . . . rotary shaft, 23 . . . first AC power source (first power source, first AC power source), 24 . . . cylinder liner (workpiece, engine component made of aluminum alloy, sealing member of engine), 25 . . . second AC power source (second power source, second AC power source), 26 . . . conductive housing (one of two electrodes), 27 . . . rod-like electrode (one of two electrodes), 28 . . . plasma generating unit.

1. A surface processing device for processing a surface of a workpiece by plasma irradiation, comprising:
a plasma generating unit for generating plasma in response to application of a voltage between two electrodes;
a first AC power source for supplying a main voltage to be applied between the two electrodes of the plasma generating unit; and
a second AC power source for supplying a bias voltage to be applied between one of the electrodes of the plasma generating unit and the workpiece, the bias voltage having the frequency different from the frequency of the main voltage,
wherein relative positions of the plasma generating unit and the workpiece are changed at a certain speed while radiating plasma from the plasma generating unit.

2. The surface processing device according to claim 1, wherein the frequency of the main voltage and the frequency of the bias voltage are set to form first recesses having a depth of 0.5 micrometers or less on the surface of the workpiece, to form second recesses having a depth of 5 micrometers, and such that the intervals of the second recesses formed on the surface of the workpiece covered with the first recesses are 1 millimeter.

3. The surface processing device according to claim 1, comprising a frequency variable unit, which varies the frequency of the second AC power source.

4. The surface processing device according to claim 1, wherein the plasma generating unit includes, as the two electrodes, a conductive housing having a space formed therein and a rod-like electrode arranged inside the conductive housing, and the plasma generating unit injects a plasma source gas into the conductive housing in a state in which the main voltage is applied between the conductive housing and the rod-like electrode, thereby generating plasma.

5. The surface processing device according to claim 1, wherein the plasma generating unit includes, as the two electrodes, a pair of flat plate electrodes arranged parallel to each other, and the plasma generating unit injects a plasma source gas into between the flat plate electrodes in a state in which the main voltage is applied between the flat plate electrodes, thereby generating plasma.

6. The surface processing device according to claim 1, wherein the device processes an inner circumferential surface of the workpiece by rotating the workpiece and the plasma generating unit relative to each other with the plasma generating unit arranged inside the workpiece formed into a circular tube.

7. The surface processing device according to claim 1, wherein the plasma generating unit is secured to a rotating member and is arranged to be able to radiate the plasma outward of the rotational direction of the rotating member, the device processes an inner circumferential surface of the workpiece by rotating the rotating member while radiating the plasma from the plasma generating unit arranged inside the workpiece formed into a circular tube.

8. The surface processing device according to claim 7, wherein the plasma generating unit is one of a plurality of plasma generating units secured to the rotating member.

9. The surface processing device according to claim 7, wherein the rotating member has a hollow rotary shaft, and the rotary shaft serves as a supply passage of the plasma source gas to the plasma generating unit.

10. The surface processing device according to claim 1, wherein the surface processing device processes a sliding surface of the workpiece.

11. The surface processing device according to claim 1, wherein the workpiece is an engine component made of an aluminum alloy.

12. The surface processing device according to claim 1, wherein the workpiece is a sealing member of an engine.

13. The surface processing device according to claim 1, wherein the workpiece is a cylinder liner of the engine.

14. A surface processing method for processing a surface of a workpiece by irradiating a surface of a workpiece with plasma generated in response to application of a main voltage between two electrodes, the method being comprising:
applying a bias voltage between one of the two electrodes and the workpiece, and setting the frequency of the main voltage supplied as an AC voltage to be different from the frequency of the bias voltage also supplied as the AC voltage; and
moving a plasma irradiation position on the surface of the workpiece at a certain speed while radiating plasma.

15. The surface processing method according to claim 14, wherein the frequency of the main voltage and the frequency of the bias voltage are set to form first recesses having a depth of 0.5 micrometers or less on the surface of the workpiece, to form second recesses having a depth of 5 micrometers, and such that the intervals of the second recesses formed on the surface of the workpiece covered with the first recesses is 1 millimeter.

16. The surface processing method according to claim 14, wherein the frequency of the bias voltage is variable.

17. The surface processing method according to claim 14, wherein the two electrodes include a conductive housing having a space formed therein and a rod-like electrode arranged inside the conductive housing, and plasma is generated by injecting a plasma source gas into the conductive housing while applying the main voltage between the conductive housing and the rod-like electrode.

18. The surface processing device according to claim 14, wherein the plasma generating unit includes, as the two electrodes, a pair of flat plate electrodes arranged parallel to each other, and the plasma generating unit injects a plasma source gas into between the flat plate electrodes in a state in which the main voltage is applied between the flat plate electrodes, thereby generating plasma.

19. The surface processing method according to claim 14, wherein the surface processing method processes a sliding surface of the workpiece.

20. The surface processing method according to claim 14, wherein the workpiece is an engine component made of an aluminum alloy.

21. The surface processing method according to claim 14, wherein the workpiece is a sealing member of an engine.

22. The surface processing method according to claim 14, wherein the workpiece is a cylinder liner of the engine.

23-34. (canceled)
